(19) United States
(12) Patent Application Publication
(10) Pub. No.: US 2022/0244640 A1
(43) Pub. Date: Aug. 4, 2022

(54) POLYIMIDE RESIN AND POSITIVE-TYPE PHOTOSENSITIVE RESIN COMPRISING THE SAME

(71) Applicant: LG Chem, Ltd., Seoul (KR)

(72) Inventors: Jiyeon SUNG, Daejeon (KR); Minyoung LIM, Daejeon (KR); Hyunsoon LIM, Daejeon (KR)

(73) Assignee: LG Chem, Ltd., Seoul (KR)

(21) Appl. No.: 17/587,563

(22) Filed: Jan. 28, 2022

(30) Foreign Application Priority Data
Feb. 4, 2021 (KR) 10-2021-0015807

(51) Int. Cl. G03F 7/039; C08G 73/10

(52) U.S. Cl. CPC G03F 7/039; C08G 73/1007; C08G 73/1085

(57) ABSTRACT

An exemplary embodiment of the present application provides a polyimide resin comprising a structure represented by Chemical Formula 1 and a positive-type photosensitive resin composition comprising the same.

### TECHNICAL FIELD

This application claims priority to and the benefit of Korean Patent Application No. 10-2021-0015807 filed in the Korean Intellectual Property Office on Feb. 4, 2021, the entire contents of which are incorporated herein by reference.

The present application relates to a polyimide resin and a positive-type photosensitive resin composition comprising the same.

### BACKGROUND ART

The market expansion and technological development of the semiconductor industry triggered by the Fourth Industrial Revolution have increased the demand for smaller semiconductors, and is also increasing the demand for semiconductor stability in more extreme environments. This is a part that requires improvement of technological capabilities in the field of semiconductor packaging. Among them, a photoresist made of a polyimide resin has attracted attention as a material capable of solving many parts. Since packaging materials remain even after being exposed and developed to form patterns unlike photoresists used in the manufacture of other internal substrates, excellent physical properties are required.

The function of forming a pattern by exposure to light is a characteristic that a photoresist needs to naturally have, and requires a higher resolution pattern to date and the ability to create a finer pattern. In addition, the packaging material requires an extremely high levels of insulation characteristics, heat resistance characteristics, physical properties, and the like capable of protecting a device from the external environment.

However, a polyimide resin has excellent characteristics such as basic insulation and physical properties of a polymer, but has a trade-off problem in that existing characteristics remarkably deteriorate when the polyimide resin is improved by a photosensitive material having a high resolution.

### DISCLOSURE

### Technical Problem

The present application has been made in an effort to provide a polyimide resin and a positive-type photosensitive resin composition comprising the same.

### Technical Solution

An exemplary embodiment of the present application provides a polyimide resin comprising a structure represented by the following Chemical Formula 1.

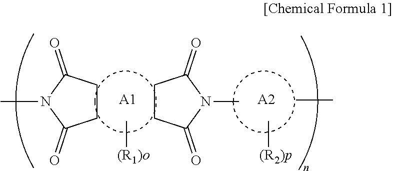

In Chemical Formula 1,

A1 is a tetravalent organic group,

A2 is a divalent organic group,

at least one of R₁ and R₂ is an acetylacetone group, and the other is independently hydrogen, an acetylacetone group, a hydroxyl group, or a substituted or unsubstituted alkyl group,

o and p are the same as or different from each other, and are each independently an integer from 0 to 10, and o+p≥1,

when o is 2 or higher, R₁'s are the same as or different from each other, and when p is 2 or higher, R₂'s are the same as or different from each other, and

n is an integer from 1 to 90, and when n is 2 or higher, structures in the parenthesis are the same as or different from each other.

Further, another exemplary embodiment of the present application provides a positive-type photosensitive resin composition comprising: a binder resin comprising the polyimide resin; a photo active compound; a cross-linking agent; a surfactant; and a solvent.

In addition, still another exemplary embodiment of the present application provides a method for preparing a polyimide resin, the method comprising: preparing a polyimide resin comprising a structure represented by the following Chemical Formula 2; and

reacting the polyimide resin with a compound comprising an acetylacetone group.

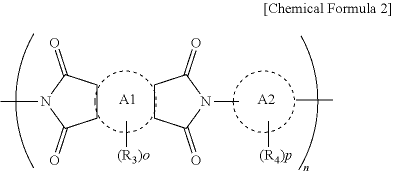

In Chemical Formula 2,

A1 is a tetravalent organic group,

A2 is a divalent organic group,

at least one of R₃ and R₄ is a hydroxyl group, and the other is independently hydrogen, a hydroxyl group, or a substituted or unsubstituted alkyl group,

o and p are the same as or different from each other, and are each independently an integer from 0 to 10, and o+p≥1,

when o is 2 or higher, R₃'s are the same as or different from each other, and when p is 2 or higher, R₄'s are the same as or different from each other, and

n is an integer from 1 to 90, and when n is 2 or higher, structures in the parenthesis are the same as or different from each other.

### Advantageous Effects

The polyimide resin according to an exemplary embodiment of the present application is characterized in that even when a separate additive is not added, the adhesion strength to a metal can be improved by comprising an acetylacetone group in the polyimide resin

### Best Mode

Hereinafter, the present application will be described in more detail.

When one member is disposed “on” another member in the present specification, this comprises not only a case where the one member is brought into contact with another member, but also a case where still another member is present between the two members.

When one part “comprises” one constituent element in the present specification, unless otherwise specifically described, this does not mean that another constituent element is excluded, but means that another constituent element may be further comprised.

Currently, as a technique of forming a metal circuit pattern on a polymer film material used as a flexible printed circuit board and a packaging dielectric material, a method of preparing a metal circuit pattern by forming a circuit pattern having a predetermined shape on the surface of a polymer on which a thin copper foil is stacked or deposited using a photoresist process, and etching copper has been generally and widely used. However, in the case of the polymer material, low wetting properties and additive contamination generated during processing cause physical and chemical interference in the catalytic treatment and plating processes, and as a result, the adhesion between the polymer and the metal becomes extremely low. To solve this problem, many surface treatment techniques are performed, and typically, methods of inducing chemical bonds of functional groups on the surface of the polymer using a solution of potassium hydroxide, and the like, and increasing a surface area due to surface irregularities have been used.

The present application intends to provide a polyimide resin having excellent adhesion strength to a metal though a method of using a separate additive or applying a surface treatment method is excluded.

The polyimide resin according to an exemplary embodiment of the present application comprises a structure represented by the following Chemical Formula 1.

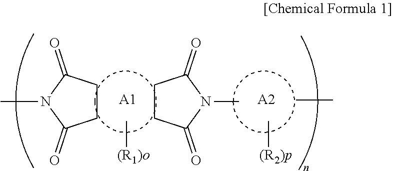

In Chemical Formula 1,

A1 is a tetravalent organic group,

A2 is a divalent organic group,

at least one of R₁ and R₂ is an acetylacetone group, and the other is independently hydrogen, an acetylacetone group, a hydroxyl group, or a substituted or unsubstituted alkyl group,

o and p are the same as or different from each other, and are each independently an integer from 0 to 10, and o+p≥1,

when o is 2 or higher, R₁'s are the same as or different from each other, and when p is 2 or higher, R₂'s are the same as or different from each other, and

n is an integer from 1 to 90, and when n is 2 or higher, structures in the parenthesis are the same as or different from each other.

The polyimide resin according to an exemplary embodiment of the present application is characterized in that even when a separate additive is not added, the adhesion strength to a metal can be improved by comprising particularly an acetylacetone group in the polyimide resin. The acetylacetone group (acac) is a ligand that forms a coordinate bond with a metal, and can form metal complexes with various metals. Copper is also comprised in the metals with which the acetylacetone group can form a coordinate bond. Therefore, in the polyimide resin according to an exemplary embodiment of the present application, an acetylacetone group in the molecule and a copper layer may form a coordinate bond with the following structural formula to improve the adhesion strength.

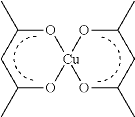

In the present specification, the “polymer” means a compound composed of the repetition of repeating units (basic units). The polymer may be represented by a macromolecule or a compound composed of macromolecules.

In the present specification, examples of substituents will be described below, but are not limited thereto.

In the present specification, a divalent organic group means a substituent having two bonding positions.

In the present specification, a tetravalent organic group means a substituent having four bonding positions.

In the present specification, the term “substituted or unsubstituted” means being substituted with one or more substituents selected from the group consisting of deuterium; a halogen group; a nitrile group; a nitro group; a hydroxyl group; —COOH; an alkoxy group; an alkyl group; a cycloalkyl group; an alkenyl group; a cycloalkenyl group; an aryl group; a heteroaryl group; and a heterocyclic group comprising one or more of N, O, S or P atom or having no substituent.

In the present specification, examples of a halogen group comprise fluorine, chlorine, bromine or iodine.

In the present specification, the alkoxy group may be straight-chained or branched, and the number of carbon atoms is not particularly limited, but may be 1 to 30, specifically 1 to 20, and more specifically 1 to 10.

In the present specification, the alkyl group may be straight-chained or branched, and the number of carbon atoms thereof is not particularly limited, but is preferably 1 to 60. According to an exemplary embodiment, the number of carbon atoms of the alkyl group is 1 to 30. According to another exemplary embodiment, the number of carbon atoms of the alkyl group is 1 to 20. According to still another exemplary embodiment, the number of carbon atoms of the alkyl group is 1 to 10. Specific examples of the alkyl group comprise a methyl group, an ethyl group, an n-propyl group, an isopropyl group, an n-butyl group, an isobutyl group, a tert-butyl group, an n-pentyl group, an n-hexyl group, an n-heptyl group, an n-octyl group, and the like, but are not limited thereto. In the present specification, a cycloalkyl group is not particularly limited, but has preferably 3 to 30 carbon atoms, and in particular, the cycloalkyl group is preferably a cyclopentyl group and a cyclohexyl group, but is not limited thereto.

In the present specification, an alkylene group means a divalent alkyl group, and the above-described description may be applied to the alkyl group.

In the present specification, a cycloalkyl group is not particularly limited, but has preferably 3 to 60 carbon atoms, and according to an exemplary embodiment, the number of carbon atoms of the cycloalkyl group is 3 to 30. According to another exemplary embodiment, the number of carbon atoms of the cycloalkyl group is 3 to 20. According to yet another exemplary embodiment, the number of carbon atoms of the cycloalkyl group is 3 to 6. Specific examples thereof comprise a cyclopropyl group, a cyclobutyl group, a cyclopentyl group, a cyclohexyl group, a cycloheptyl group, a cyclooctyl group, and the like, but are not limited thereto.

In the present specification, a cycloalkylene group means a divalent cycloalkyl group, and the above-described description may be applied to the cycloalkyl group.

In the present specification, the alkenyl group may be straight-chained or branched, and the number of carbon atoms thereof is not particularly limited, but is preferably 2 to 60. According to an exemplary embodiment, the number of carbon atoms of the alkenyl group is 2 to 30. According to another exemplary embodiment, the number of carbon atoms of the alkenyl group is 2 to 20. According to yet another exemplary embodiment, the number of carbon atoms of the alkenyl group is 2 to 10. Specific examples of the alkenyl group are preferably an alkenyl group in which an aryl group, such as a stylbenyl group and a styrenyl group, is substituted, but are not limited thereto.

In the present specification, a cycloalkenyl group is not particularly limited, but has preferably 3 to 60 carbon atoms, and according to an exemplary embodiment, the number of carbon atoms of the cycloalkenyl group is 3 to 30. According to yet another exemplary embodiment, the number of carbon atoms of the cycloalkenyl group is 3 to 20. According to yet another exemplary embodiment, the number of carbon atoms of the cycloalkenyl group is 3 to 6. Examples of the cycloalkenyl group are preferably a cyclopentenyl group and a cyclohexenyl group, but are not limited thereto.

In the present specification, an aryl group is not particularly limited, but has preferably 6 to 60 carbon atoms, and may be a monocyclic aryl group or a polycyclic aryl group. According to an exemplary embodiment, the number of carbon atoms of the aryl group is 6 to 30. According to an exemplary embodiment, the number of carbon atoms of the aryl group is 6 to 20. Examples of a monocyclic aryl group as the aryl group comprise a phenyl group, a biphenyl group, a terphenyl group, and the like, but are not limited thereto. Examples of the polycyclic aryl group comprise a naphthyl group, an anthracenyl group, an indenyl group, a phenanthrenyl group, a pyrenyl group, a perylenyl group, a triphenyl group, a chrysenyl group, a fluorenyl group, and the like, but are not limited thereto.

In the present specification, an arylene group means a divalent aryl group, and the above-described description may be applied to the aryl group.

In the present specification, the heterocyclic group is a heterocyclic group comprising O, N or S as a heteroatom, and the number of carbon atoms thereof is not particularly limited, but is 2 to 30, specifically 2 to 20. Examples of the heterocyclic group comprise a thiophene group, a furan group, a pyrrole group, an imidazole group, a thiazole group, an oxazole group, an oxadiazole group, a triazole group, a pyridyl group, a bipyridyl group, a triazine group, an acridyl group, a pyridazine group, a qinolinyl group, an isoquinoline group, an indole group, a carbazole group, a benzoxazole group, a benzoimidazole group, a benzothiazole group, a benzocarbazole group, a benzothiophene group, a dibenzothiophene group, a benzofuranyl group, a dibenzofuran group, and the like, but are not limited thereto.

In the present specification, the above-described description on the heterocyclic group may be applied to a heteroaryl group except for an aromatic heteroaryl group.

In the present specification, an aromatic ring may be an aryl group or a heteroaryl group, and the above-described description may be applied to the aryl group or the heteroaryl group.

In the present specification, the aliphatic ring may mean a ring other than the aromatic ring.

In the present specification, when A1 is a tetravalent organic group, A1 may be adopted without limitation.

In the present specification, when A2 is a divalent organic group, A2 may be adopted without limitation.

In an exemplary embodiment of the present application, A1 may be a substituted or unsubstituted aliphatic ring, or a substituted or unsubstituted aromatic ring.

In an exemplary embodiment of the present application, the

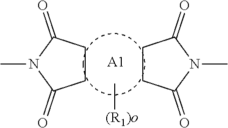

structure of Chemical Formula 1 may be induced from the following compounds.

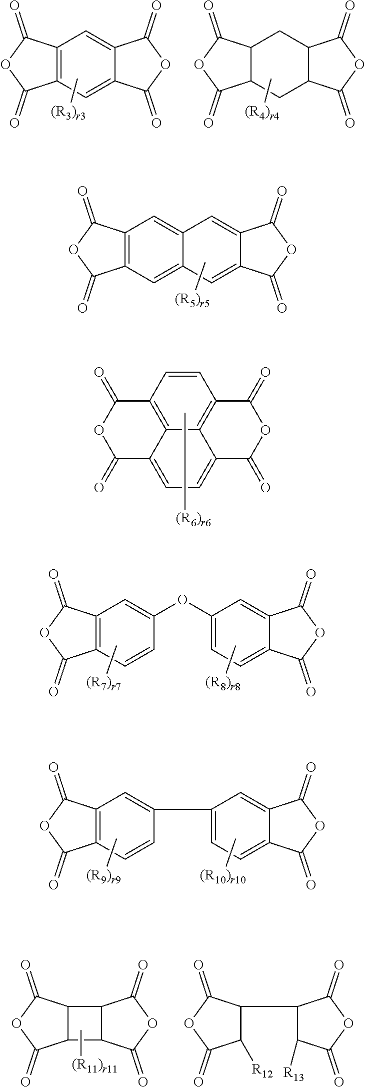

In the compounds,

R₃ to R₁₃ are each independently hydrogen, an acetylacetone group, a hydroxyl group, or a substituted or unsubstituted alkyl group,

r₃ is an integer from 0 to 2, r4 to r6, and rll are each independently an integer from 0 to 4, and r7 to r10 are each independently an integer from 0 to 3,

R₃'s are the same as or different from each other when r3 is 2, R₄'s are the same as or different from each other when r4 is 2 or higher, R₅'s are the same as or different from each other when r5 is 2 or higher, R₆'s are the same as or different from each other when r6 is 2 or higher, Re's are the same as or different from each other when r7 is 2 or higher, Rg's are the same as or different from each other when r8 is 2 or higher, R₉'s are the same as or different from each other when r9 is 2 or higher, R₁₀'s are the same as or different from each other when r10 is 2 or higher , and R₁₁'s are the same as or different from each other when r11 is 2 or higher.

In an exemplary embodiment of the present application, A2 is represented by (L1)a, L1 is a substituted or unsubstituted alkylene group, a substituted or unsubstituted cycloalkylene group, or a substituted or unsubstituted arylene group, a is an integer from 1 to 3, and when a is 2 or higher, L1's are the same as or different from each other.

In an exemplary embodiment of the present application, A2 may be represented by the following structural formulae.

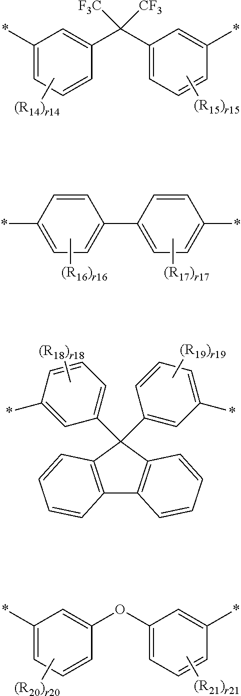

In the structural formulae,

[symbol] means a moiety bonded to Chemical Formula 1,

R₁₄ to R₂₁ are each independently hydrogen, an acetylacetone group, a hydroxyl group, or a substituted or unsubstituted alkyl group,

r14 to r21 are each independently an integer from 0 to 4, and

R₁₄'s are the same as or different from each other when r14 is 2 or higher, R₁₅'s are the same as or different from each other when r15 is 2 or higher, R₁₆'s are the same as or different from each other when r16 is 2 or higher, R₁₇'s are the same as or different from each other when r17 is 2 or higher, R₁₈'s are the same as or different from each other when r18 is 2 or higher, R₁₉'s are the same as or different from each other when r19 is 2 or higher, and R₂₀'s are the same as or different from each other when r20 is 2 or higher.

In an exemplary embodiment of the present application, the polyimide resin may further comprise a structure represented by the following Chemical Formula 3 or 4.

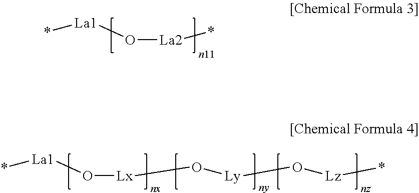

In Chemical Formulae 3 and 4,

[symbol] means a moiety bonded to Chemical Formula 1,

La1 and La2 are the same as or different from each other, and are each independently a direct bond; or a substituted or unsubstituted alkylene group,

Lx, Ly and Lz are the same as or different from each other, and are each independently a substituted or unsubstituted alkylene group,

n11 is a real number from 1 to 30, and

nx, ny and nz are each independently a real number from 1 to 50.

In an exemplary embodiment of the present specification, the polyimide resin may have a weight average molecular weight of 1,000 g/mol to 70,000 g/mol, more preferably 3,000 g/mol to 50,000 g/mol. When the weight average molecular weight of the polyimide resin is less than 1,000 g/mol, the produced insulating film may be brittle and the adhesive strength may deteriorate. In addition, when the weight average molecular weight of the polyimide resin exceeds 70,000 g/mol, the sensitivity is lowered and the polyimide resin may not be developed or scum may remain, which is not preferred.

The weight average molecular weight is one of the average molecular weights in which the molecular weight is not uniform and the molecular weight of any polymer material is used as a reference, and is a value obtained by averaging the molecular weight of a component molecular species of a polymer compound having a molecular weight distribution by a weight fraction.

The weight average molecular weight may be measured by a gel permeation chromatography (GPC) method.

The positive-type photosensitive resin composition according to an exemplary embodiment of the present application comprises: a binder resin comprising the polyimide resin; a photo active compound; a cross-linking agent; a surfactant; and a solvent.

In an exemplary embodiment of the present application, based on 100 parts by weight of the binder resin comprising the polyimide resin, it is possible to comprise 1 part by weight to 40 parts by weight of the photo active compound; 5 parts by weight to 50 parts by weight of the cross-linking agent; 0.05 part by weight to 5 parts by weight of the surfactant; and 50 parts by weight to 500 parts by weight of the solvent.

When each of the constituent elements is comprised in the positive-type photosensitive resin composition in the above-described range of parts by weight, the polyimide resin is developed in an alkaline developer and may not only have high mechanical properties and heat resistance, but also improve the adhesion strength to a metal.

The photo active compound may be specifically a quinonediazide compound. As the quinonediazide compound, for example, TPA529, THA515 or PAC430 manufactured by Miwon Commercial Co., Ltd. may be used, but the compound is not limited thereto.

The cross-linking agent is not particularly limited, and may be used without limitation as long as the cross-linking agent is applied to the art. For example, as the cross-linking agent, it is possible to use 2-[[4-[2-[4-[1,1-bis[4-(oxiran-2-ylmethoxy)phenyl]ethyl]phenyl]propan-2-yl]phenoxyl]methyl]oxirane, 4,4′-methylenebis(N,N-bis(oxiran-2-ylmethyl)aniline), YD-127, YD-128, YD-129, YDF-170, YDF-175, and YDF-180 manufactured by Kukdo Chemical Co., Ltd., EXA-4850 manufactured by DIC Corporation, and the like.

The surfactant is a silicone-based surfactant or a fluorine-based surfactant, and specifically, as the silicone-based surfactant, it is possible to use BYK-077, BYK-085, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341v344, BYK-345v346, BYK-348, BYK-354, BYK-355, BYK-356, BYK-358, BYK-361, BYK-370, BYK-371, BYK-375, BYK-380, BYK-390 and the like, which are manufactured by BYK-Chemie Co., Ltd., and as the fluorine-based surfactant, it is possible to use F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF-1116SF, TF-1131, TF1132, TF1027SF, TF-1441, TF-1442 and the like, which are manufactured by DaiNippon Ink & Chemicals, Inc. (DIC), but the surfactants are not limited thereto.

As the solvent, it is possible to employ a compound known to enable the formation of a photosensitive resin composition in the art to which the present invention pertains without particular limitation. As a non-limiting example, the solvent may be one or more compounds selected from the group consisting of esters, ethers, ketones, aromatic hydrocarbons, and sulfoxides.

The ester solvent may be ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, gamma-butyrolactone, epsilon-caprolactone, delta-valerolactone, alkyl oxyacetate (for example: methyl oxyacetate, ethyl oxyacetate, butyl oxyacetate (for example, methyl methoxyacetate, ethyl methoxyacetate, butyl methoxyacetate, methyl ethoxyacetate, ethyl ethoxyacetate, and the like)), 3-oxypropionic acid alkyl esters (for example: methyl 3-oxypropionate, ethyl 3-oxypropionate, and the like (for example, methyl 3-methoxypropionate, ethyl 3-methoxypropionate, methyl 3-ethoxypropionate, ethyl 3-ethoxypropionate, and the like)), 2-oxypropionic acid alkyl esters (for example: methyl 2-oxypropionate, ethyl 2-oxypropionate, propyl 2-oxypropionate, and the like (for example, methyl 2-methoxypropionate, ethyl 2-methoxypropionate, propyl 2-methoxypropionate, methyl 2-ethoxypropionate, ethyl 2-ethoxypropionate)), methyl 2-oxy-2-methylpropionate and ethyl 2-oxy-2-methylpropionate (for example, methyl 2-methoxy-2-methylpropionate, ethyl 2-ethoxy-2-methylpropionate, and the like), methyl pyruvate, ethyl pyruvate, propyl pyruvate, methyl acetoacetate, ethyl acetoacetate, methyl 2-oxobutyrate, ethyl 2-oxobutyrate, or the like.

The ether solvent may be diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, or the like.

The ketone solvent may be methyl ethyl ketone, cyclohexanone, cyclopentanone, 2-heptanone, 3-heptanone, N-methyl-2-pyrrolidone, or the like.

The aromatic hydrocarbon solvent may be toluene, xylene, anisole, limonene, or the like.

The sulfoxide solvent may be dimethyl sulfoxide or the like.

Further, another exemplary embodiment of the present application provides a method for preparing a polyimide resin, the method comprising: preparing a polyimide resin comprising a structure represented by the following Chemical Formula 2; and reacting the polyimide resin with a compound comprising an acetylacetone group.

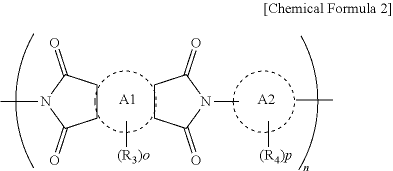

In Chemical Formula 2,

A1 is a tetravalent organic group,

A2 is a divalent organic group,

at least one of R₃ and R₄ is a hydroxyl group, and the other is independently hydrogen, a hydroxyl group, or a substituted or unsubstituted alkyl group,

o and p are the same as or different from each other, and are each independently an integer from 0 to 10, and o+p≥1,

when o is 2 or higher, R₃'s are the same as or different from each other, and when p is 2 or higher, R₄'s are the same as or different from each other, and

n is an integer from 1 to 90, and when n is 2 or higher, structures in the parenthesis are the same as or different from each other.

In an exemplary embodiment of the present application, a hydroxyl group of the polyimide resin of Chemical Formula 2 may be replaced with an acetylacetone group.

In an exemplary embodiment of the present application, a compound comprising the acetylacetone group may be ethoxyacetylacetone.

Another exemplary embodiment of the present application provides an insulating film comprising the positive-type photosensitive resin composition or a cured product thereof.

The insulating film may comprise the positive-type photosensitive resin composition as it is.

The insulating film may comprise a cured product of the positive-type photosensitive resin composition.

Examples of a light source for curing the photosensitive resin composition according to an exemplary embodiment of the present application comprise mercury vapor arc, carbon arc, Xe arc, and the like, which emit a light with a wavelength of 250 nm to 450 nm, but are not always limited thereto.

The insulating film may be further subjected to a step of heat-treating the positive-type photosensitive resin composition after curing the positive-type photosensitive resin composition, if necessary. The heat treatment may be performed by a heating means such as a hot plate, a hot air circulation furnace, and an infrared furnace, and may be performed at a temperature of 180° C. to 250° C., or 190° C. to 220° C.

The insulating film exhibits excellent chemical resistance and mechanical properties, and thus may be preferably applied to an insulating film of a semiconductor device, an interlayer insulating film for a redistribution layer, and the like. Further, the insulation may be applied to photoresists, etching resists, solder top resists, and the like.

The insulating film may comprise a support or substrate.

The support or substrate is not particularly limited, and those known in the art may be used. For example, a substrate for an electronic component or a predetermined wiring pattern formed on the substrate may be exemplified. Examples of the substrate comprise a metal substrate such as silicon, silicon nitride, titanium, tantalum, palladium, titanium tungsten, copper, chromium, iron, aluminum, gold, and nickel, a glass substrate, and the like. As a material of the wiring pattern, for example, copper, solder, chromium, aluminum, nickel, gold and the like may be used, but the material is not limited thereto.

The application method is not particularly limited, but a spray method, a roll coating method, a spin coating method, and the like may be used, and in general, the spin coating method is widely used. Further, an application film is formed, and then in some cases, the residual solvent may be partially removed under reduced pressure.

In an exemplary embodiment of the present application, the insulating film may have a thickness of 1 μm to 100 μm. When the thickness range of the insulating film is satisfied, it is possible to obtain an insulating film which is excellent not only in chemical resistance and mechanical properties, which are desired in the present application, but also in adhesion strength to a metal. The thickness of the insulating film may be measured using a scanning electron microscope (SEM).

Another exemplary embodiment of the present application provides a semiconductor device comprising the insulating film.

The semiconductor device may be manufactured by further comprising various parts typically used in the art in addition to the insulating film.

### Mode for Invention

Hereinafter, the present application will be described in detail with reference to Examples for specifically describing the present application. However, the Examples according to the present application may be modified in various forms, and it is not interpreted that the scope of the present application is limited to the Examples described below. The Examples of the present application are provided for more completely explaining the present application to the person with ordinary skill in the art.

### EXAMPLES

### Synthesis Example 1

### Synthesis of Polyimide Resin A1

After 100 mmol of 2,2-bis(3-amino-4-hydroxyphenyl)hexafluoropropane (Bis-APAF) and 300 g of propylene glycol methyl ether acetate (PGMEA) were sequentially introduced into a 1,000-mL round bottom flask and completely dissolved by increasing the temperature to 120° C. and stirring the flask, the flask was cooled to 80° C., 97 mmol of tetrahydro-[3,3′-bifuran]-2,2′,5,5′-tetraone (BT-100) and 6 mmol of trimellitic anhydride (TMA) were introduced thereto, and then the resulting mixture was stirred along with 30 g of toluene at 150° C. After the components were completely dissolved, the resulting solution was cooled to 50° C., and then 3 mmol of gamma valerolactone (r-VL) and 7 mmol of triethyl amine (TEA) were diluted with 10 g of propylene glycol monomethyl acetate (PGMEA), and the resulting solution was introduced thereinto. After a Dean-Stark distillation apparatus was installed such that water could be removed in the reaction by the apparatus, the mixture was stirred at 175° C. for 16 hours. After the toluene added to the mixed solution was removed, a polymer was recovered by cooling the solution to room temperature. The weight average molecular weight (Mw) of the recovered polymer was confirmed using gel permeation chromatography (GPC), and was determined to be 23,900 g/mol. In addition, the polydispersity index (PDI) of the prepared polymer was 1.54.

### Synthesis Example 2

### Synthesis of Polyimide Resin B1

Polymer resin B1 was synthesized in the same manner as in the method of Synthesis Example 1, except that 4,4′-oxydiphthalic anhydride (ODPA) was used instead of BT-100. The weight average molecular weight (Mw) and polydispersity index (PDI) of the recovered polymer were 17,202 g/mol and 2.46, respectively.

### Synthesis Example 3

### Synthesis of Polyimide Resin C1

Polymer resin C1 was synthesized in the same manner as in the method of Synthesis Example 1, except that biphenyl-tetracarboxylic acid dianhydride (BPDA) was used instead of BT-100. The weight average molecular weight (Mw) and polydispersity index (PDI) of the recovered polymer were 17,766 g/mol and 2.40, respectively.

### Synthesis Example 4

### Synthesis of Polyimide Resin D1

Polymer resin D1 was synthesized in the same manner as in the method of Synthesis Example 1, except that 2,2-dihydroxybenzidine was used instead of Bis-APAF. The weight average molecular weight (Mw) and polydispersity index (PDI) of the recovered polymer were 20,500 g/mol and 1.58, respectively.

### Synthesis Example 5

### Synthesis of Polyimide Resin E1

Polyimide resin E1 was synthesized in the same manner as in the method of Synthesis Example 4, except that ODPA was used instead of BT-100. The weight average molecular weight (Mw) and polydispersity index (PDI) of the recovered polymer were 17,898 g/mol and 2.57, respectively.

### Synthesis Example 6

### Synthesis of Polyimide Resin F1

Polyimide resin F1 was synthesized in the same manner as in the method of Synthesis Example 4, except that BPDA was used instead of BT-100. The weight average molecular weight (Mw) and polydispersity index (PDI) of the recovered polymer were 20,679 g/mol and 2.49, respectively.

### Synthesis Example 7

### Synthesis of polyimide resin G1

Polyimide resin G1 was synthesized in the same manner as in the method of Synthesis Example 1, except that 60 mmol of Bis-APAF and 40 mmol of O,O′-Bis(2-aminopropyl) polypropylene glycol-block-polyethylene glycol-block-polypropylene glycol (ED-600) were used instead of 100 mmol of Bis-APAF, and 47 mmol of BT-100 and 50 mmol of ODPA were used instead of 97 mmol of BT-100. The weight average molecular weight (Mw) and polydispersity index (PDI) of the recovered polymer were 20,751 g/mol and 2.74, respectively.

### Synthesis Example 8

### Synthesis of Polyimide Resin H1

Polyimide resin H1 was synthesized in the same manner as in the method of Synthesis Example 7, except that BPDA was used instead of BT-100. The weight average molecular weight (Mw) and polydispersity index (PDI) of the recovered polymer were 14,793 g/mol and 2.65, respectively.

### Synthesis Example 9

### Synthesis of Polyimide Resin I1

Polyimide resin I1 was synthesized in the same manner as in the method of Synthesis Example 7, except that 2,2′-dihydroxybenzidine was used instead of Bis-APAF. The weight average molecular weight (Mw) and polydispersity index (PDI) of the recovered polymer were 17,257 g/mol and 2.81, respectively.

### Synthesis Example 10

### Synthesis of Polyimide Resin J1

Polyimide resin J1 was synthesized in the same manner as in the method of Synthesis Example 8, except that 2,2′-dihydroxybenzidine was used instead of Bis-APAF. The weight average molecular weight (Mw) and polydispersity index (PDI) of the recovered polymer were 16,855 g/mol and 2.48, respectively.

### Synthesis Example 11

### Synthesis of Polyimide Resins A2 to J2

As shown in the following General Synthesis Example, an acetylacetone group can be easily introduced into the molecule by a reaction of ethoxyacetylacetone and a hydroxyl group.

### General Synthesis Example

### Synthesis of acetylacetone group

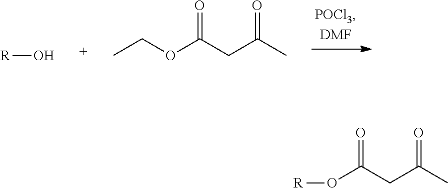

Polyimide resins A2 to J2 were synthesized by the following General Synthesis Example Each of the polymide resins Al to Jl and ethoxyacetylacetone were dissolved in anhydrous tetrahydrofuran (THF), the temperature was lowered to 0° C. using an ice bath, and nitrogen atmosphere was prepared. While nitrogen atmosphere at 0° C. was maintained in other flasks, POCl₃ and dimethylformamide (DMF) were mixed in anhydrous THF and maintained in the flask for 30 minutes. A mixture of POCl₃ and DMF was slowly added to the flask in which the resin was dissolved using a syringe. After the addition was completed, the resulting mixture was slowly warmed to room temperature, and then heated and stirred at 60° C. for 15 hours using an oil bath. After the reaction was completed, the mixture was cooled to room temperature and washed with a basic solution using sodium bicarbonate and distilled water. The obtained organic solution was distilled under reduced pressure to remove THE

The polymer in which an acetylacetone group was introduced into the polyimide resin A1 is marked as polyimide resin A2. Polymers in which an acetylacetone group was introduced into the above-described polyimide resins B1 to J1 using the same method are marked as polyimide resins B2 to J2, respectively.

### Examples 1 to 10 and Comparative Examples 1 to 4

### Preparation of positive-type photosensitive resin composition

A positive-type photosensitive resin composition was prepared by mixing 15 parts by weight of a photo active compound (TPA529), 25 parts by weight of a cross-linking agent (2-[[4-[2-[4-[1,1-bis[4-(oxiran-2-ylmethoxy)phenyl]ethyl]phenyl]propan-2-yl]phenoxy]methyl]oxirane), 0.1 part by weight of a surfactant (BYK-307, manufactured by BYK-Chemie) and 200 parts by weight of a solvent (PGMEA) based on 100 parts by weight of the polyimide resin shown in the following Table 1. The positive-type photosensitive resin composition prepared as described above were allowed to pass through a 0.2-μm filter and evaluated by removing impurities in the solution.

### Experimental Example

After wafers were spin-coated with the positive-type photosensitive resin compositions prepared in the Examples and Comparative Examples using wafers on which Ti and Cu were vapor-deposited to a thickness of 100 nm or more, and coated to a thickness of 6 μm, the solvents remaining on the wafers were completely removed by baking at a temperature of 105° C. or more in order to remove the solvent. After the wafers were irradiated with a constant exposure of 100 mJ/cm² to 900 mJ/cm² using a stepper that emits i-line wavelength, the wafers were developed with a developer for 120 seconds, subjected to a rinsing process with a rinse solution, and then post baked at a temperature of 200° C. or less for 2 hours.

### Evaluation conditions of positive-type photosensitive resin composition

Prebake: 105° C./120 s

Exposure: i-line Stepper, 100 mJ/cm² to 900 mJ/cm²

Development: 2.38 wt% tetramethylammonium hydroxide (TMAH) solution 23° C./120 s

Rinse: DI water rinse

Post Bake: 200° C./2 hrs

The pattern characteristics were confirmed using a wafer that had been completely post baked, the photosensitive resin composition coated on the wafer was cured and then formed into a film, and the mechanical properties and thermal characteristics thereof were measured.

For pattern developability, the shape and size of the pattern were measured using a scanning electron microscope (SEM), and mechanical properties were measured using a universal testing machine (UTM).

### Pattern Developability

The shape and size of the pattern were measured by measuring a completely developed part from a thickness of 5 pm to a contact hole pattern lower part of 10 μm using the SEM, and a case where the hole pattern of 10 pm was completely developed was described as good. The case where the pattern lower part was not developed was described as poor.

Good: ⊚

Fair: Δ

Poor: X

### Adhesion Strength

A check shape of 10 rows, 10 columns was incised at an interval of 2 mm using a single-edged blade on a film after the wafer was coated with the resin and the resin was cured. The number of cells peeled out of 100 cells on top of this was counted by peeling with a cellophane tape (registered trademark) to evaluate the adhesion characteristics between the metal material and the resin-cured film.

Less than 10: ⊚

10 or more and less than 20: Δ

20 or more: X

TABLE 1

| | | Pattern | Adhesion |
|---|---|---|---|
| | Polyimide resin | developability | strength |
| Example 1 | Polyimide resin A2 | Δ | ⊚ |
| Example 2 | Polyimide resin B2 | ⊚ | ⊚ |
| Example 3 | Polyimide resin C2 | ⊚ | ⊚ |
| Example 4 | Polyimide resin D2 | Δ | ⊚ |
| Example 5 | Polyimide resin E2 | ⊚ | ⊚ |
| Example 6 | Polyimide resin F2 | ⊚ | ⊚ |
| Example 7 | Polyimide resin G2 | ⊚ | ⊚ |
| Example 8 | Polyimide resin H2 | ⊚ | ⊚ |
| Example 9 | Polyimide resin I2 | ⊚ | ⊚ |
| Example 10 | Polyimide resin J2 | ⊚ | ⊚ |
| Comparative | Polyimide resin A1 | Δ | Δ |
| Example 1 | | | |
| Comparative | Polyimide resin D1 | X | Δ |
| Example 2 | | | |
| Comparative | Polyimide resin G1 | Δ | Δ |
| Example 3 | | | |
| Comparative | Polyimide resin I1 | Δ | Δ |
| Example 4 | | | |

As described in the results, the polyimide resin according to an exemplary embodiment of the present application is characterized in that even when a separate additive is not added, the adhesion strength to a metal can be improved by comprising an acetylacetone group in the polyimide resin.

1. A polyimide resin comprising a structure represented by the following Chemical Formula 1: 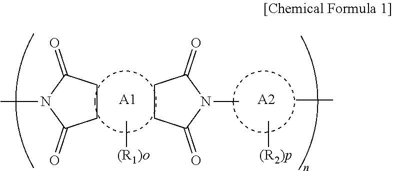
in Chemical Formula 1,
A1 is a tetravalent organic group,
A2 is a divalent organic group,
at least one of R₁ and R₂ is an acetylacetone group, and the other is independently hydrogen, an acetylacetone group, a hydroxyl group, or a substituted or unsubstituted alkyl group,
o and p are the same as or different from each other, and are each independently an integer from 0 to 10, and o+p≥1,
when o is 2 or higher, R₁'s are the same as or different from each other, and when p is 2 or higher, R₂'s are the same as or different from each other, and
n is an integer from 1 to 90, and when n is 2 or higher, structures in the parenthesis are the same as or different from each other.

2. The polyimide resin of claim 1, wherein Al is a substituted or unsubstituted aliphatic ring, or a substituted or unsubstituted aromatic ring.

3. The polyimide resin of claim 1, wherein A2 is represented by (L1)a,
L1 is a substituted or unsubstituted alkylene group, a substituted or unsubstituted cycloalkylene group, or a substituted or unsubstituted arylene group, and
a is an integer from 1 to 3, and when a is 2 or higher, L1's are the same as or different from each other.

4. A positive-type photosensitive resin composition comprising: a binder resin comprising the polyimide resin of claim 1; a photo active compound; a cross-linking agent; a surfactant; and a solvent.

5. The positive-type photosensitive resin composition of claim 4, wherein based on 100 parts by weight of the binder resin comprising the polyimide resin,
1 part by weight to 40 parts by weight of the photo active compound;
5 parts by weight to 50 parts by weight of the cross-linking agent;
0.05 part by weight to 5 parts by weight of the surfactant; and
50 parts by weight to 500 parts by weight of the solvent are comprised.

6. A method for preparing a polyimide resin, the method comprising:
preparing a polyimide resin comprising a structure represented by the following Chemical Formula 2; and
reacting the polyimide resin with a compound comprising an acetylacetone group: 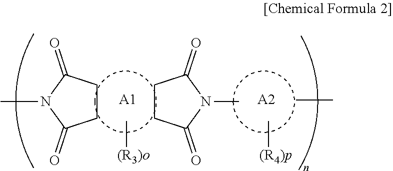
in Chemical Formula 2,
A1 is a tetravalent organic group,
A2 is a divalent organic group,
at least one of R₃ and R₄ is a hydroxyl group, and the other is independently hydrogen, a hydroxyl group, or a substituted or unsubstituted alkyl group,
o and p are the same as or different from each other, and are each independently an integer from 0 to 10, and o+p≥1,
when o is 2 or higher, R₃'s are the same as or different from each other, and when p is 2 or higher, R₄'s are the same as or different from each other, and
n is an integer from 1 to 90, and when n is 2 or higher, structures in the parenthesis are the same as or different from each other.

7. The method of claim 6, wherein the compound comprising the acetylacetone group is ethoxyacetylacetone.
